(19) United States
(12) Patent Application Publication
(10) Pub. No.: US 2024/0030172 A1
(43) Pub. Date: Jan. 25, 2024

(54) THREE DIMENSIONAL UNIVERSAL CHIPLET INTERCONNECT AS ON-PACKAGE INTERCONNECT

(71) Applicant: Intel Corporation, Santa Clara, CA (US)

(72) Inventors: Debendra Das Sharma, Saratoga (US); Peter Z. Onufryk, Flanders, NJ (US); Gerald S. Pasdast, San Jose (US); Sathya Narasimman Tiagaraj, San Jose (US)

(73) Assignee: Intel Corporation, Santa Clara, CA (US)

(21) Appl. No.: 18/479,014

(22) Filed: Sep. 30, 2023

Related U.S. Application Data
(60) Provisional application No. 63/513,069, filed on Jul. 11, 2023.

(51) Int. Cl. H01L 23/00; H01L 25/065

(52) U.S. Cl. CPC H01L 24/16; H01L 25/0657; H01L 2225/06513; H01L 2224/16145; H01L 2924/1431; H01L 2924/381

(57) ABSTRACT

Methods and apparatus relating to a Universal Chiplet Interconnect Express™ (UCIe™)-Three Dimensional (UCIe-3D™) interconnect which may be utilized as an on-package interconnect are described. In one embodiment, an interconnect communicatively couples a first physical layer module of a first chiplet on a semiconductor package to a second physical layer module of a second chiplet on the semiconductor package. A first Network-on-chip Controller (NoC) logic circuitry controls the first physical layer module. A second NoC logic circuitry controls the second physical layer module. Other embodiments are also claimed and disclosed.

### RELATED APPLICATION

The present application relates to and claims priority from U.S. Provisional Patent Application Ser. No. 63/513,069, filed Jul. 11, 2023, entitled “UNIVERSAL CHIPLET INTERCONNECT EXPRESS (UCIE)-THREE DIMENSION (3D) AS AN ON-PACKAGE INTERCONNECT,” which is incorporated herein in its entirety and for all purposes.

### FIELD

The present disclosure generally relates to the field of interconnects. More particularly, an embodiment relates to a Universal Chiplet Interconnect Express™ (UCIe™)-Three Dimensional (UCIe-3D™) interconnect which may be utilized as an on-package interconnect.

### BACKGROUND

A “chiplet” generally refers to an integrated circuit device (such as an integrated circuit die) that may include one or more functional blocks capable of performing one or more operations. For example, a chiplet may be included on a semiconductor package to perform one or more operations associated with tasks such as compute, networking, storage, acceleration, etc.

Leaders in semiconductors, packaging, Intellectual Property (IP) block suppliers, foundries, and cloud service providers have been joining together to drive an open chiplet ecosystem via a group referred to as the Universal Chiplet Interconnect Express™ (UCIe™) Consortium. The UCIe Consortium was formed in March of 2022 and incorporated in June of 2022.

Such an open chiplet ecosystem is envisioned to provide plug-and-play, backward compatibility, and/or improved power/performance/cost metrics across the industry, e.g., to allow for continuous innovation to meet the needs of an evolving compute landscape.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates an example of two chiplets coupled through nine UCIe-3D links, in accordance with various embodiments.

FIG. 2 illustrates an example of connections between Network-on-chip Controllers (NoCs) and physical layer (PHY) blocks, in accordance with various embodiments.

FIG. 3 illustrates an example of configuration of a UCIe-3D link, in accordance with various embodiments.

FIG. 4 illustrates an alternative example configuration of a UCIe-3D link, in accordance with various embodiments.

FIG. 5 illustrates an example computing system which may be used to practice various aspects of the disclosure, in accordance with various embodiments.

FIG. 6 illustrates a block diagram of an embodiment of a computing system, which may be utilized in various embodiments discussed herein.

FIG. 7 illustrates a block diagram of an embodiment of a computing system, which may be utilized in various embodiments discussed herein.

FIG. 8 illustrates various components of a processer in accordance with some embodiments.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware (such as logic circuitry or more generally circuitry or circuit), software, firmware, or some combination thereof.

As mentioned above, the UCIe may provide plug-and-play, backward compatibility, and/or improved power/performance/cost metrics across the industry, e.g., to allow for continuous innovation to meet the needs of an evolving compute landscape. However, scalability may be an issue with current UCIe implementations.

To this end, some embodiments relate to a Universal Chiplet Interconnect express-Three Dimensional (UCIe-3D) interconnect which may be utilized as an on-package interconnect. The proposed UCIe-3D provides a next-generation die-to-die interconnect, e.g., to scale from 25 micrometer (“um” or “micron”) bump-pitch to sub-1u bump-pitch, which may support improved power-efficiency, area, latency, and/or reliability in a uniform approach. Such embodiments would provide lower latency, higher bandwidth, lower silicon area, and/or lower power consumption than existing solutions.

As used herein, the term “module” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

Moreover, some embodiments discussed herein relate to use of UCIe-3D or some other next-generation die-to-die interconnect. Specifically, embodiments may relate to use of UCIe-3D to scale from a 25 micrometer bump-pitch to a bump-pitch that is less than 1 micron. As used herein, the term “pitch” may refer to a distance from the center of one bump to the center of an adjacent bump. Embodiments may provide advantages in terms of one or more of power-efficiency, area, latency, and/or reliability.

Embodiments may relate to one or more of the following aspects. Such aspects may be considered to be part of the next generation of UCIe technology, which may be referred to herein as UCIe-3D:
Circuit and logic may be required to fit within the designated bump area (which may be referred to as “bump-limited”). Given the relatively high density (e.g., density on the order of terra-bytes/second/square millimeter), such density may result in lower operating frequencies and a more simplified circuit than legacy UCIe-compliant circuits (e.g., UCIe 1.0-compliant circuits).
Embodiments may not require a die-to-die (D2D) adapter. Layering with UCIe generally utilizes a D2D adapter to facilitate communication between a physical layer (e.g., using a raw D2D interface (RDI)) and a protocol layer (e.g., using a flit aware D2D interface (FDI)). In some embodiments, the electrical characteristics may be defined such that the bit error rate (BER) is between approximately 10⁻²⁷ and approximately 10⁻³⁰. With the bit error rate so-defined, no cyclic redundancy check (CRC) or replay mechanism may be necessary (which would typically be provided by a D2D adapter).
Embodiments may include a hardened physical layer (PHY) (i.e., the PHY that is available as a hard IP). As discussed herein, a “hard” or “hardened” logic/IP/circuit generally refers to logic circuitry that has fixed locations of the components such as transistors and wires, and logic circuitry that may typically only be changed by the IP vendor. The PHY may act as an inverter and/or driver in some embodiments. The system-on-chip (“SoC” or “SOC”) logic may couple directly to the PHY.
Some or all of the debug and/or testability hooks may be positioned inside of a common block across some or all of the UCIe-3D links that are coupled to the SoC logic network inside a chiplet.
The interconnect may not include an electrostatic discharge (ESD) circuit. Specifically, the ESD circuit may be omitted for bump pitches at or below approximately three microns.
Lane repair may be performed as a cluster-wide repair, and be managed/orchestrated by the SoC logic.

More generally, embodiments herein may relate to next-generation UCIe/UCIe-3D interconnects that are unidirectional, and support both two-dimensional (2D), 2D+ (which may be referred to as 2.xD), and 3D connectivity. Embodiments may be usable at bump pitches between approximately 25 microns and 1 micron (or lower). Embodiments may operate at the chiplet internal frequency, or even a lower frequency.

Embodiments may result in orders of magnitude improvement in bandwidth and power efficiency over the legacy (e.g., UCIe 1.0) interconnects. The lower frequency and shorter distance across the dies may make the circuits simpler, and allow them to fit within the bump area with significantly lower power consumption than the legacy (e.g., UCIe 1.0) interconnects. Because such interconnects may have lower BER (as described above) due to the relatively shorter distance and/or lower frequency, a D2D adapter may be removed in some embodiments (as described above).

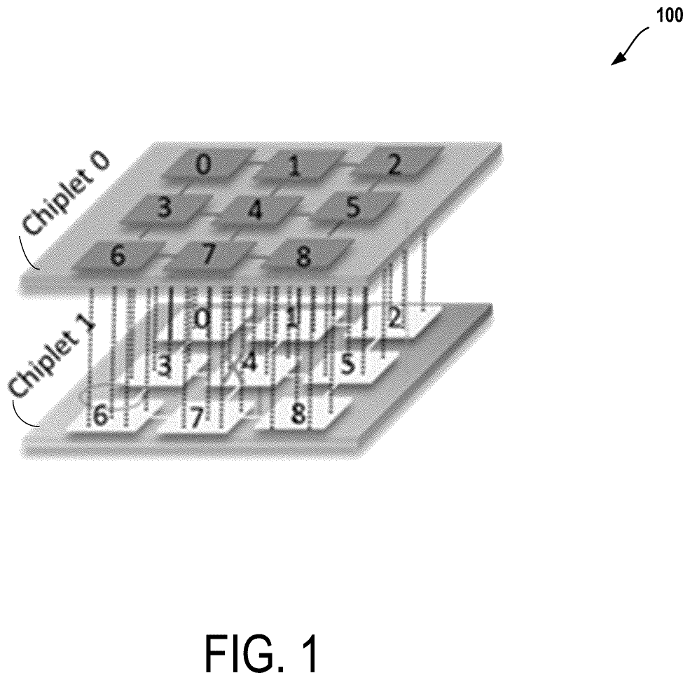

In some embodiments, two chiplets may be coupled using multiple independent modules, e.g., with each hardened UCIe-3D PHY directly controlled by the SoC logic (e.g., Network-on-chip Controller or “NoC), as shown in FIG. 1. Specifically, FIG. 1 depicts an example of two chiplets coupled through 9 UCIe-3D links (numbered as 0 to 8 on each chiplet). In this example, the NoCs are coupled using a 2D mesh topology. However, in other embodiments, other topologies may be supported.

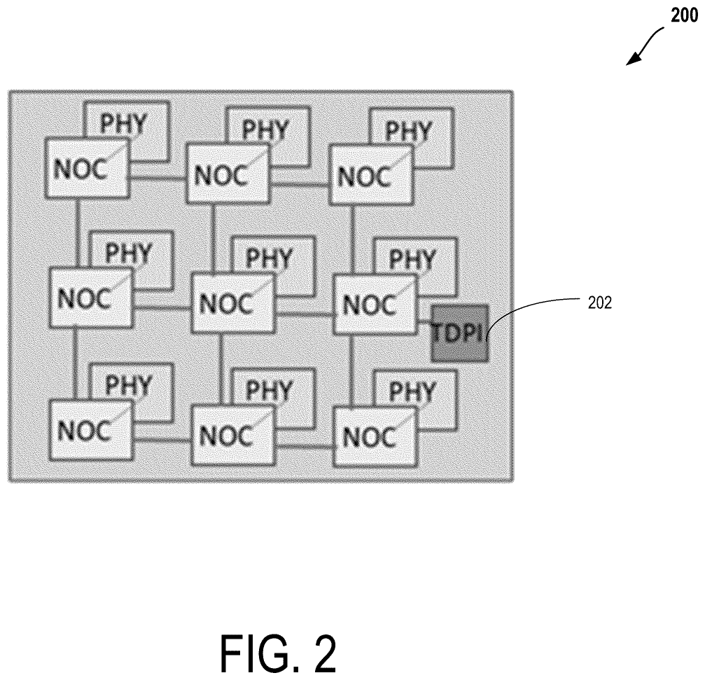

The common functionality across all PHYs may be orchestrated/managed by a common control block in the chiplet to amortize the overhead. An example of this is shown in FIG. 2. Specifically, in FIG. 2, respective ones of a plurality of NoCs may be coupled directly to one or more UCIe-3D PHY blocks that are hardened.

The PHY may be implemented using a square bump layout with dedicated sub-clusters for data vs. non-data (e.g., address, error correction code (ECC), spares etc.). Each chiplet may have a common test, debug, and/or pattern generation/checking infrastructure 202 (labeled as “TDPI” or Test, Debug, and Pattern generation/checking Infrastructure) coupled to one or more NoCs. The TDPI 202 may be responsible for orchestrating/managing training, testing, and debug across the UCIe-3D links by using the routing network of NoCs. As a result, the PHY may not have any configuration or status registers in some embodiments. The PHY may have a square profile, and may match the size of the NoC to reduce or minimize fan-in/fan-out of wires so that the wire lengths are close to the least distance between NoC and PHY, which may help minimize the area, power, and/or latency.

In embodiments, defect tolerance may be managed at the NoC/chiplet level, as shown in FIGS. 1-4. In one embodiment, failures in the NoC or the UCIe-3D link may be routed around by other NoCs. An example of this may be seen in FIG. 1.

As mentioned earlier, some embodiments may not utilize a D2D adapter. Rather, these embodiments may have the NoC directly interface with the UCIe-3D circuits. The NoC designer may set the supply voltage level to the appropriate value to meet the NoC logic timing. The most efficient UCIe-3D interconnect may be one that can operate on the same supply as the NoC to avoid special supply requirements.

Some embodiments may rely upon a lean D2D data path that includes a re-timing flop stage at the UCIe-3D transmit (TX) bump followed by an appropriately sized inverter driver to meet its own up to 5 Volt (V) charged-device model (CDM) electrostatic discharge (ESD) requirement (e.g., via parasitic diodes) as well as the slew rate requirements across a Hybrid Bonded Interconnect (HBI) or Hybrid Bonded (HB) connection into the receive (RX) inverter plus ESD on the other die. Some embodiments may approach or include a 0V CDM requirement as bump pitches decrease to at or below 3 um so that the UCIe-3D PHY fits within the bump area.

The described UCIe-3D approach may be amenable to synthesis and Automatic Place and Route (APR) tools and adaptable to a wide range of floorplans. It may enable static timing analysis for timing closure for the D2D crossing. To facilitate this, some embodiments may specify timing at the HB or HBI bump boundary and continue with the forwarded clock architecture of UCIe-S and UCIe-A to establish a set of clock-to-data specifications at bump pins.

Furthermore, since the same architecture may be used across both sides of the 3D connection, asymmetric bandwidth needs may be addressed by arraying different number(s) of input/output (IO) modules for each side of the connection. The TX, RX, and clock circuits may be implemented as inverters that create a matched data and clock path with data launched at the rising clock edge and captured with the corresponding forwarded falling clock edge. The forwarded clock source may be the same as the NoC clock source and shared on both chiplet dies to avoid power and latency associated with clock domain crossings.

At bump pitches approaching 3 um and below, embodiments may experience a fractional NoC frequency (FNF) D2D crossing that may be helpful for power optimization. For example, a D2D crossing at a 1 um bump pitch running at a native NoC frequency of approximately 4 gigahertz (GHz) may consume more power than running twice the number of wires at 2 GHz. Loopback schemes such as near end (within die) or far end (D2D) can be incorporated into the overall data path to enable detection of defects at sort testing before assembling multiple dies within a package.

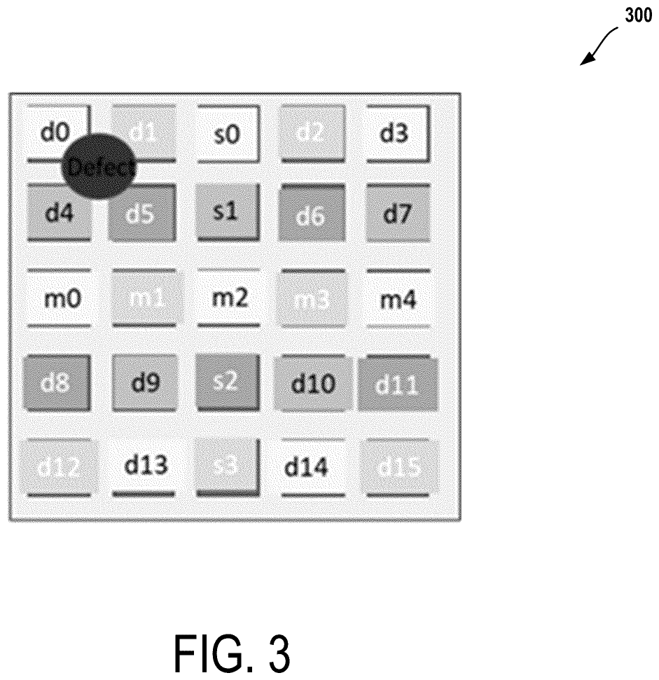

FIG. 3 depicts an example configuration related to UCIe-3D. Specifically, the UCIe-3D link may include an array of 25 sub-clusters, arranged as a 5×5 square array. Each sub-cluster may have 16 wires for a total of 400 wires. Of these 25 sub-cluster, 16 sub-clusters may be data (d0-d15) wires for a total of 256 data wires; five sub-clusters may be for address/control/ECC/sideband/clock/other miscellaneous functions (m0-m4) for a total of 80 wires; four sub-clusters may be optionally spare (or they could be used for data or miscellaneous other tasks) s0-s3. If used as spares, the NoC may be configured to repair a defect.

Given the tight geometries, a defect may impact multiple sub-clusters, e.g., up to four adjacent ones, as shown in FIG. 3. If spares are used, the NoC may deploy the spares (s0, s1, etc.) associated with each sub-cluster as follows: s0: mux{d0, d3, m0, m2, m4, d13, d14}, s1: mux{d4, d7, d9, d10}, s2: mux{d5, d6, d8, d11}, and s3: mux{d1, d2, m1, m3, d12, d15}. This arrangement may ensure that any failure impacting up to four nearby sub-modules have a unique spare to use. Using the spares may cause multiplexing (or muxing) of data and will result in additional gate-count. In the example defect above, s0 will carry d0, s3 will carry d1, s1 will carry d4, and s2 will carry d5.

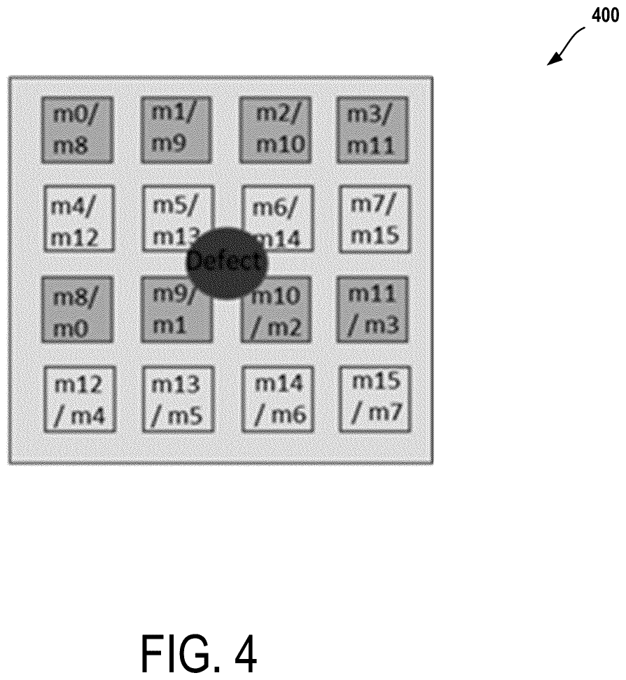

FIG. 4 depicts an alternate implementation of a UCIe-3D link. The UCIe-3D link may include 16 sub-clusters, each with 20+ wires, 16 of which may be data and the rest may be address/command/ECC/etc. In this arrangement, the NoC may optionally choose to degrade the link to half width (which would be a 2:1 mux) or it may route around the failed link as shown in FIG. 1 (box 3 of chiplet 1 being bypassed). If the link level degradation is used, the contents of rows 0 and 1 may be interchanged with 2 and 3, respectively. For the fault scenario in this example, only rows 0 and 3 may be used with the transfer taking double the cycles relative to the non-degraded mode.

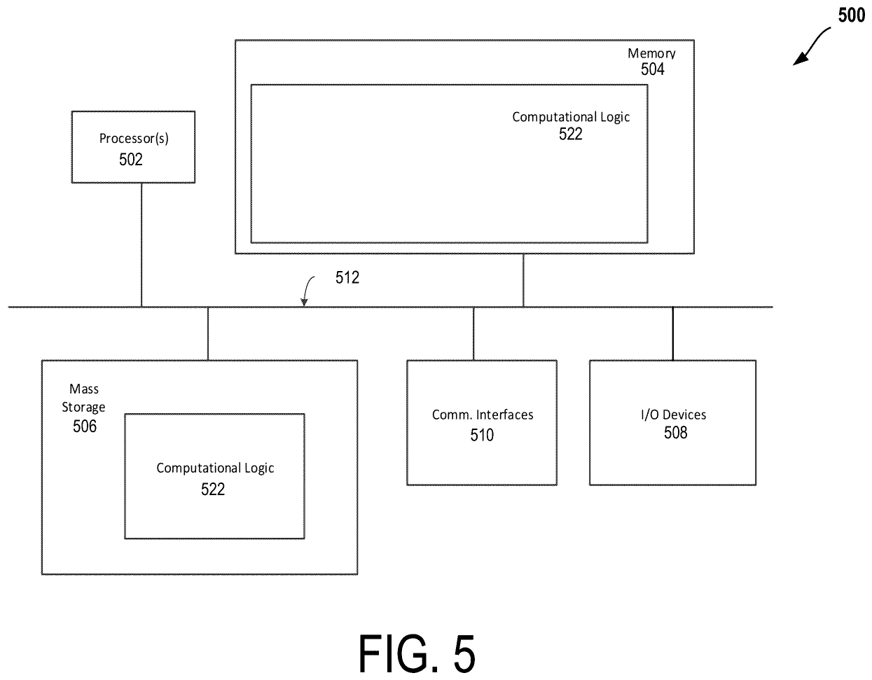

One or more components discussed with reference to FIGS. 5-8 (including but not limited to I/O devices, memory/storage devices, graphics/processing cards/devices, network/bus/audio/display/graphics controllers, wireless transceivers, etc.) may communicate via the chiplet interconnects discussed above with reference to FIGS. 1-4.

More particularly, FIG. 5 illustrates an example computing device 500 which may be utilized to practice aspects of the present disclosure, in accordance with various embodiments. For example, the example computing device 500 may be suitable to implement the functionalities associated with any of FIGS. 1-4, or some other method, process, or technique described herein, in whole or in part.

As shown, computing device 500 may include one or more processors 502, each having one or more processor cores, and system memory 504. The processor 502 may include any type of single-core or multi-core processors. Each processor core may include a central processing unit (CPU), and one or more level of caches. The processor 502 may be implemented as an integrated circuit. The computing device 500 may include mass storage devices 506 (such as diskette, hard drive, volatile memory (e.g., dynamic random access memory (DRAM)), compact disc read only memory (CD-ROM), digital versatile disk (DVD) and so forth). In general, system memory 504 and/or mass storage devices 506 may be temporal and/or persistent storage of any type, including, but not limited to, volatile and non-volatile memory, optical, magnetic, and/or solid state mass storage, and so forth. Volatile memory may include, but not be limited to, static and/or dynamic random access memory. Non-volatile memory may include, but not be limited to, electrically erasable programmable read only memory, phase change memory, resistive memory, and so forth.

The computing device 500 may further include input/output (I/O) devices 508 such as a display, keyboard, cursor control, remote control, gaming controller, image capture device, one or more three-dimensional cameras used to capture images, and so forth, and communication interfaces 510 (such as network interface cards, modems, infrared receivers, radio receivers (e.g., Bluetooth™), and so forth). I/O devices 508 may be suitable for communicative connections with three-dimensional cameras or user devices. In some embodiments, I/O devices 508 when used as user devices may include a device necessary for implementing the functionalities of receiving an image captured by a camera.

The communication interfaces 510 may include communication chips (not shown) that may be configured to operate the device 500 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 510 may operate in accordance with other wireless protocols in other embodiments.

The above-described computing device 500 elements may be coupled to each other via system bus 512, which may represent one or more buses. In the case of multiple buses, they may be bridged by one or more bus bridges (not shown). Each of these elements may perform its conventional functions known in the art. In particular, system memory 504 and mass storage devices 506 may be employed to store a working copy and a permanent copy of the programming instructions implementing the operations and functionalities associated with any of FIGS. 1-4, or some other method, process, or technique described herein, in whole or in part, generally shown as computational logic 522. Computational logic 522 may be implemented by assembler instructions supported by processor(s) 502 or high-level languages that may be compiled into such instructions.

The permanent copy of the programming instructions may be placed into mass storage devices 506 in the factory, or in the field, though, for example, a distribution medium (not shown), such as a compact disc (CD), or through communication interfaces 510 (from a distribution server (not shown)).

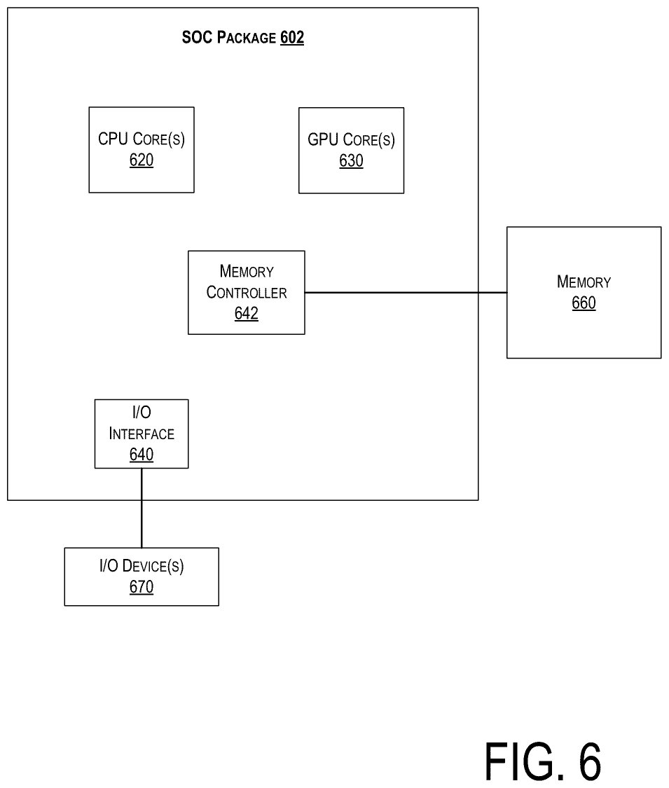

FIG. 6 illustrates a block diagram of a System-on-Chip (“SOC” or “SoC”) package in accordance with an embodiment. As illustrated in FIG. 6, SOC 602 includes one or more Central Processing Unit (CPU) or processor cores 620, one or more Graphics Processor Unit (GPU) cores 630, an Input/Output (I/O) interface 640, and a memory controller 642. Various components of the SOC package 602 may be coupled to an interconnect or bus such as discussed herein with reference to the other figures. Also, the SOC package 602 may include more or less components, such as those discussed herein with reference to the other figures. Further, each component of the SOC package 620 may include one or more other components, e.g., as discussed with reference to the other figures herein. In one embodiment, SOC package 602 (and its components) is provided on one or more Integrated Circuit (IC) die, e.g., which are packaged into a single semiconductor device.

As illustrated in FIG. 6, SOC package 602 is coupled to a memory 660 via the memory controller 642. In an embodiment, the memory 660 (or a portion of it) can be integrated on the SOC package 602.

The I/O interface 640 may be coupled to one or more I/O devices 670, e.g., via an interconnect and/or bus such as discussed herein with reference to other figures. I/O device(s) 670 may include one or more of a keyboard, a mouse, a touchpad, a display, an image/video capture device (such as a camera or camcorder/video recorder), a touch screen, a speaker, or the like.

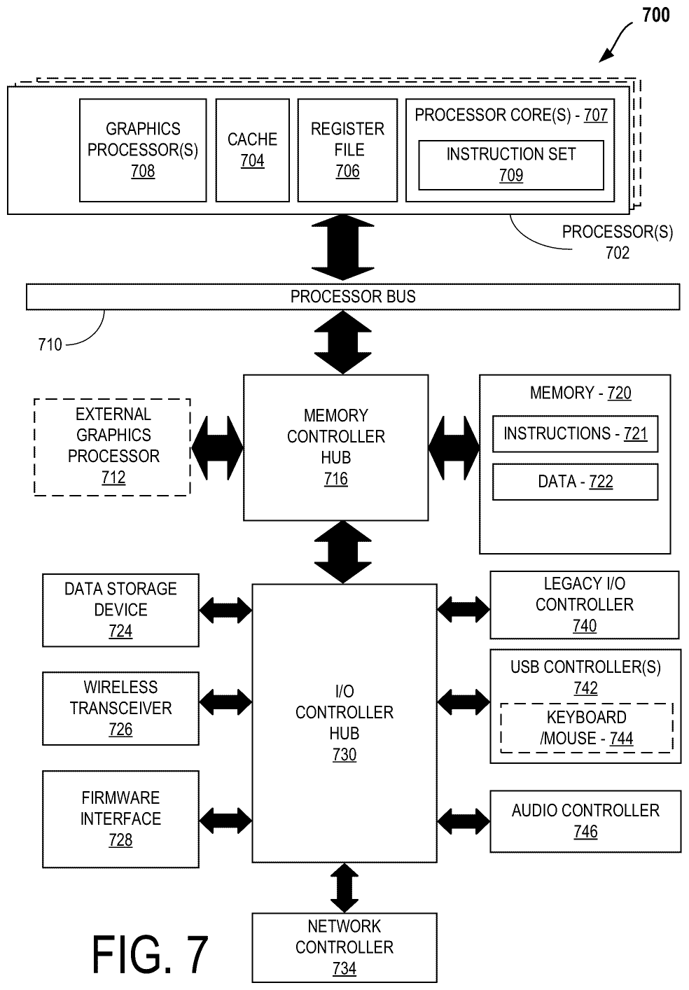

FIG. 7 is a block diagram of a processing system 700, according to an embodiment. In various embodiments the system 700 includes one or more processors 702 and one or more graphics processors 708, and may be a single processor desktop system, a multiprocessor workstation system, or a server system having a large number of processors 702 or processor cores 707. In an embodiment, the system 700 is a processing platform incorporated within an SoC integrated circuit for use in mobile, handheld, or embedded devices.

An embodiment of system 700 can include, or be incorporated within a server-based gaming platform, a game console, including a game and media console, a mobile gaming console, a handheld game console, or an online game console. In some embodiments system 700 is a mobile phone, smart phone, tablet computing device or mobile Internet device. Data processing system 700 can also include, couple with, or be integrated within a wearable device, such as a smart watch wearable device, smart eyewear device, augmented reality device, or virtual reality device. In some embodiments, data processing system 700 is a television or set top box device having one or more processors 702 and a graphical interface generated by one or more graphics processors 708.

In some embodiments, the one or more processors 702 each include one or more processor cores 707 to process instructions which, when executed, perform operations for system and user software. In some embodiments, each of the one or more processor cores 707 is configured to process a specific instruction set 709. In some embodiments, instruction set 709 may facilitate Complex Instruction Set Computing (CISC), Reduced Instruction Set Computing (RISC), or computing via a Very Long Instruction Word (VLIW). Multiple processor cores 707 may each process a different instruction set 709, which may include instructions to facilitate the emulation of other instruction sets. Processor core 707 may also include other processing devices, such a Digital Signal Processor (DSP).

In some embodiments, the processor 702 includes cache memory 704. Depending on the architecture, the processor 702 can have a single internal cache or multiple levels of internal cache. In some embodiments, the cache memory is shared among various components of the processor 702. In some embodiments, the processor 702 also uses an external cache (e.g., a Level-3 (L3) cache or Last Level Cache (LLC)) (not shown), which may be shared among processor cores 707 using known cache coherency techniques. A register file 706 is additionally included in processor 702 which may include different types of registers for storing different types of data (e.g., integer registers, floating point registers, status registers, and an instruction pointer register). Some registers may be general-purpose registers, while other registers may be specific to the design of the processor 702.

In some embodiments, processor 702 is coupled to a processor bus 710 to transmit communication signals such as address, data, or control signals between processor 702 and other components in system 700. In one embodiment the system 700 uses an exemplary ‘hub’ system architecture, including a memory controller hub 716 and an Input Output (I/O) controller hub 730. A memory controller hub 716 facilitates communication between a memory device and other components of system 700, while an I/O Controller Hub (ICH) 730 provides connections to I/O devices via a local I/O bus. In one embodiment, the logic of the memory controller hub 716 is integrated within the processor.

Memory device 720 can be a dynamic random access memory (DRAM) device, a static random access memory (SRAM) device, flash memory device, phase-change memory device, or some other memory device having suitable performance to serve as process memory. In one embodiment the memory device 720 can operate as system memory for the system 700, to store data 722 and instructions 721 for use when the one or more processors 702 executes an application or process. Memory controller hub 716 also couples with an optional external graphics processor 712, which may communicate with the one or more graphics processors 708 in processors 702 to perform graphics and media operations.

In some embodiments, ICH 730 enables peripherals to connect to memory device 720 and processor 702 via a high-speed I/O bus. The I/O peripherals include, but are not limited to, an audio controller 746, a firmware interface 728, a wireless transceiver 726 (e.g., Wi-Fi, Bluetooth), a data storage device 724 (e.g., hard disk drive, flash memory, etc.), and a legacy I/O controller 740 for coupling legacy (e.g., Personal System 2 (PS/2)) devices to the system. One or more Universal Serial Bus (USB) controllers 742 connect input devices, such as keyboard and mouse 744 combinations. A network controller 734 may also couple to ICH 730. In some embodiments, a high-performance network controller (not shown) couples to processor bus 710. It will be appreciated that the system 700 shown is exemplary and not limiting, as other types of data processing systems that are differently configured may also be used. For example, the I/O controller hub 730 may be integrated within the one or more processor 702, or the memory controller hub 716 and I/O controller hub 730 may be integrated into a discreet external graphics processor, such as the external graphics processor 712.

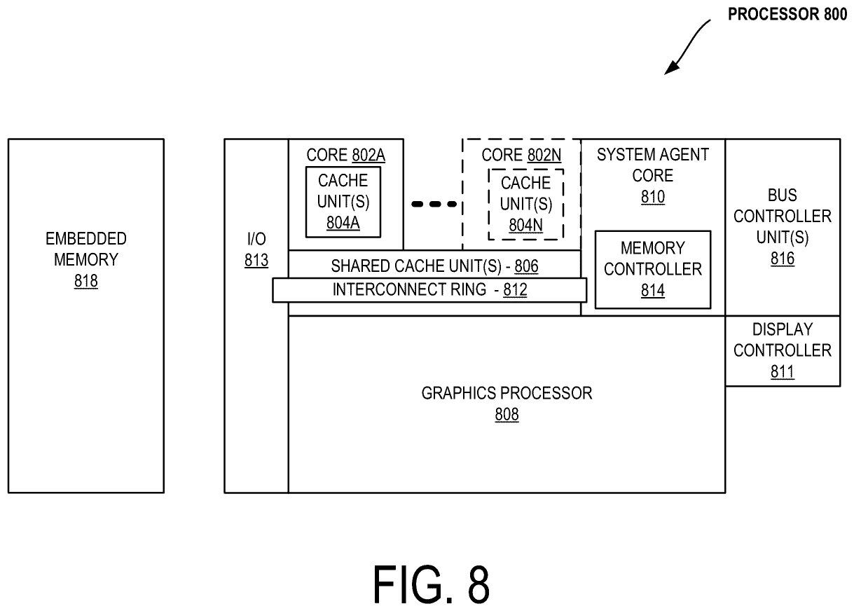

FIG. 8 is a block diagram of an embodiment of a processor 800 having one or more processor cores 802A to 802N, an integrated memory controller 814, and an integrated graphics processor 808. Those elements of FIG. 8 having the same reference numbers (or names) as the elements of any other figure herein can operate or function in any manner similar to that described elsewhere herein, but are not limited to such. Processor 800 can include additional cores up to and including additional core 802N represented by the dashed lined boxes. Each of processor cores 802A to 802N includes one or more internal cache units 804A to 804N. In some embodiments each processor core also has access to one or more shared cached units 806.

The internal cache units 804A to 804N and shared cache units 806 represent a cache memory hierarchy within the processor 800. The cache memory hierarchy may include at least one level of instruction and data cache within each processor core and one or more levels of shared mid-level cache, such as a Level 2 (L2), Level 3 (L3), Level 4 (L4), or other levels of cache, where the highest level of cache before external memory is classified as the LLC. In some embodiments, cache coherency logic maintains coherency between the various cache units 806 and 804A to 804N.

In some embodiments, processor 800 may also include a set of one or more bus controller units 816 and a system agent core 810. The one or more bus controller units 816 manage a set of peripheral buses, such as one or more Peripheral Component Interconnect buses (e.g., PCI, PCI Express). System agent core 810 provides management functionality for the various processor components. In some embodiments, system agent core 810 includes one or more integrated memory controllers 814 to manage access to various external memory devices (not shown).

In some embodiments, one or more of the processor cores 802A to 802N include support for simultaneous multi-threading. In such embodiment, the system agent core 810 includes components for coordinating and operating cores 802A to 802N during multi-threaded processing. System agent core 810 may additionally include a power control unit (PCU), which includes logic and components to regulate the power state of processor cores 802A to 802N and graphics processor 808.

In some embodiments, processor 800 additionally includes graphics processor 808 to execute graphics processing operations. In some embodiments, the graphics processor 808 couples with the set of shared cache units 806, and the system agent core 810, including the one or more integrated memory controllers 814. In some embodiments, a display controller 811 is coupled with the graphics processor 808 to drive graphics processor output to one or more coupled displays. In some embodiments, display controller 811 may be a separate module coupled with the graphics processor via at least one interconnect, or may be integrated within the graphics processor 808 or system agent core 810.

In some embodiments, a ring-based interconnect unit 812 is used to couple the internal components of the processor 800. However, an alternative interconnect unit may be used, such as a point-to-point interconnect, a switched interconnect, or other techniques, including techniques well known in the art. In some embodiments, graphics processor 808 couples with the ring interconnect 812 via an I/O link 813.

The exemplary I/O link 813 represents at least one of multiple varieties of I/O interconnects, including an on package I/O interconnect which facilitates communication between various processor components and a high-performance embedded memory module 818, such as an eDRAM (or embedded DRAM) module. In some embodiments, each of the processor cores 802 to 802N and graphics processor 808 use embedded memory modules 818 as a shared Last Level Cache.

In some embodiments, processor cores 802A to 802N are homogenous cores executing the same instruction set architecture. In another embodiment, processor cores 802A to 802N are heterogeneous in terms of instruction set architecture (ISA), where one or more of processor cores 802A to 802N execute a first instruction set, while at least one of the other cores executes a subset of the first instruction set or a different instruction set. In one embodiment processor cores 802A to 802N are heterogeneous in terms of microarchitecture, where one or more cores having a relatively higher power consumption couple with one or more power cores having a lower power consumption. Additionally, processor 800 can be implemented on one or more chips or as an SoC integrated circuit having the illustrated components, in addition to other components.

The following examples pertain to further embodiments. Example 1 includes an apparatus comprising: an interconnect to communicatively couple a first physical layer module of a first chiplet on a semiconductor package to a second physical layer module of a second chiplet on the semiconductor package; a first Network-on-chip Controller (NoC) logic circuitry to control the first physical layer module; and a second NoC logic circuitry to control the second physical layer module; wherein at least one of the first physical layer module and the second physical layer module is hardened Intellectual Property (IP) module.

Example 2 includes the apparatus of example 1, wherein the hardened IP module comprises fixed locations of components. Example 3 includes the apparatus of example 1, wherein the hardened IP module comprises fixed locations of components which can only be modified by an IP vendor. Example 4 includes the apparatus of example 1, wherein the hardened IP module comprises fixed locations of components, wherein the components comprise at least one or more transistors and one or more wires.

Example 5 includes the apparatus of example 1, wherein at least one of the first NoC logic circuitry and the second NoC logic circuitry is capable to perform one or more lane repair operations for the interconnect. Example 6 includes the apparatus of example 1, wherein at least one of the first NoC logic circuitry and the second NoC logic circuitry is perform one or more lane repairs for the interconnect as a cluster-wide repair. Example 7 includes the apparatus of example 1, wherein the physical layer modules on the first chiplet and the second chiplet are to be arranged with dedicated sub-clusters for transmission of data and non-data signals.

Example 8 includes the apparatus of example 7, wherein the non-data signals comprise at least one of: address, control, error correction code, sideband, clock, spare, and miscellaneous signals. Example 9 includes the apparatus of example 7, wherein at least one of the first NoC logic circuitry and the second NoC logic circuitry is capable to deploy a spare for a plurality of the dedicated sub-clusters. Example 10 includes the apparatus of example 1, wherein at least one of the first NoC logic circuitry and the second NoC logic circuitry is capable to address a communication defect in a link of the interconnect by one of: reducing a width of the link or routing communication around the failed link.

Example 11 includes the apparatus of example 1, wherein at least one of the first chiplet and the second chiplet comprises a common logic circuitry, coupled to one or more NoC logic circuitry, to perform training, testing, and/or debug across one or more links of the interconnect. Example 12 includes the apparatus of example 1, wherein the first chiplet and the second chiplet have a bump pitch between approximately 25 microns and 1 micron. Example 13 includes the apparatus of example 1, wherein an electrostatic discharge (ESD) circuit is to be omitted for a chiplet of the semiconductor package with bump pitches at or below approximately three microns. Example 14 includes the apparatus of example 1, wherein the interconnect supports a bit error rate (BER) between approximately 10-27 and approximately 10-30.

Example 15 includes a System-on-Chip (SoC) comprising: a processor coupled to a die-to-die interconnect; the die-to-die interconnect to facilitate communication between a plurality of chiplets; a first Network-on-chip Controller (NoC) logic circuitry to interface with the die-to-die interconnect and to control a first physical layer module; and a second NoC logic circuitry to interface with the die-to-die interconnect and to control a second physical layer module, wherein at least one of the first physical layer module and the second physical layer module is hardened Intellectual Property (IP) module.

Example 16 includes the SoC of example 15, wherein at least one of the first NoC logic circuitry and the second NoC logic circuitry is perform one or more lane repairs for the interconnect as a cluster-wide repair. Example 17 includes the SoC of example 15, wherein the physical layer modules on the first chiplet and the second chiplet are to be arranged with dedicated sub-clusters for transmission of data and non-data signals.

Example 18 includes one or more non-transitory computer-readable media comprising one or more instructions that when executed on a processor configure the processor to perform one or more operations to: communicate with a first physical layer module of a first chiplet and a second physical layer module of a second chiplet via a chiplet interconnect; wherein a first Network-on-chip Controller (NoC) logic circuitry is to interface with the chiplet interconnect to control the first physical layer module and wherein a second NoC logic circuitry is to interface with the chiplet interconnect to control the second physical layer module.

Example 19 includes the one or more non-transitory computer-readable media of example 18, further comprising one or more instructions that when executed on the processor configure the processor to perform one or more operations to cause at least one of the first NoC logic circuitry and the second NoC logic circuitry to perform one or more lane repair operations for the chiplet interconnect. Example 20 includes the one or more non-transitory computer-readable media of example 18, further comprising one or more instructions that when executed on the processor configure the processor to perform one or more operations to cause at least one of the first NoC logic circuitry and the second NoC logic circuitry to address a communication defect in a link of the interconnect by one of: reducing a width of the link or routing communication around the failed link.

Example 21 includes a die-to-die (D2D) interconnect configured to allow connections at bump pitches less than or equal to approximately 25 micrometers (microns). Example 22 includes the D2D interconnect of example 21, wherein the D2D interconnect is configured to allow connections at bump pitches less than or equal to approximately 1 micron. Example 23 includes the D2D interconnect of any of examples 21-22, and/or some other example herein, wherein the D2D interconnect does not include a D2D adapter. Example 24 includes the D2D interconnect of any of examples 21-23, and/or some other example herein, wherein the D2D interconnect has a bit error rate (BER) of less than or equal to 10-27. Example 25 includes the D2D interconnect of any of examples 21-24, and/or some other example herein, wherein system on chip (SoC) logic of a die that is coupled with the D2D interconnect is coupled directly to a physical layer (PHY) layer of the D2D interconnect. Example 26 includes the D2D interconnect of any of examples 21-25, and/or some other example herein, wherein the D2D interconnect does not include an electrostatic discharge (ESD) circuit. Example 27 includes the D2D interconnect of example 26, wherein the D2D interconnect is at a bump pitch of less than or equal to approximately 3 microns.

Example 28 includes an apparatus comprising means to perform a method as set forth in any preceding example. Example 29 includes machine-readable storage including machine-readable instructions, when executed, to implement a method or realize an apparatus as set forth in any preceding example.

In various embodiments, one or more operations discussed with reference to FIG. 1 et seq. may be performed by one or more components (interchangeably referred to herein as “logic”) discussed with reference to any of the figures.

In some embodiments, the operations discussed herein, e.g., with reference to FIG. 1 et seq., may be implemented as hardware (e.g., logic circuitry), software, firmware, or combinations thereof, which may be provided as a computer program product, e.g., including one or more tangible (e.g., non-transitory) machine-readable or computer-readable media having stored thereon instructions (or software procedures) used to program a computer to perform a process discussed herein. The machine-readable medium may include a storage device such as those discussed with respect to the figures.

Further, while various embodiments described herein use the term System-on-a-Chip or System-on-Chip (“SoC” or “SOC”) to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems, the various dies, tiles and/or chiplets can be physically and/or electrically coupled together by a package structure including, for example, various packaging substrates, interposers, active interposers, photonic interposers, interconnect bridges, and the like. The disaggregated collection of discrete dies, tiles, and/or chiplets can also be part of a System-on-Package (“SoP”).

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
an interconnect to communicatively couple a first physical layer module of a first chiplet on a semiconductor package to a second physical layer module of a second chiplet on the semiconductor package;
a first Network-on-chip Controller (NoC) logic circuitry to control the first physical layer module; and
a second NoC logic circuitry to control the second physical layer module;
wherein at least one of the first physical layer module and the second physical layer module is hardened Intellectual Property (IP) module.

2. The apparatus of claim 1, wherein the hardened IP module comprises fixed locations of components.

3. The apparatus of claim 1, wherein the hardened IP module comprises fixed locations of components which can only be modified by an IP vendor.

4. The apparatus of claim 1, wherein the hardened IP module comprises fixed locations of components, wherein the components comprise at least one or more transistors and one or more wires.

5. The apparatus of claim 1, wherein at least one of the first NoC logic circuitry and the second NoC logic circuitry is capable to perform one or more lane repair operations for the interconnect.

6. The apparatus of claim 1, wherein at least one of the first NoC logic circuitry and the second NoC logic circuitry is perform one or more lane repairs for the interconnect as a cluster-wide repair.

7. The apparatus of claim 1, wherein the physical layer modules on the first chiplet and the second chiplet are to be arranged with dedicated sub-clusters for transmission of data and non-data signals.

8. The apparatus of claim 7, wherein the non-data signals comprise at least one of: address, control, error correction code, sideband, clock, spare, and miscellaneous signals.

9. The apparatus of claim 7, wherein at least one of the first NoC logic circuitry and the second NoC logic circuitry is capable to deploy a spare for a plurality of the dedicated sub-clusters.

10. The apparatus of claim 1, wherein at least one of the first NoC logic circuitry and the second NoC logic circuitry is capable to address a communication defect in a link of the interconnect by one of: reducing a width of the link or routing communication around the failed link.

11. The apparatus of claim 1, wherein at least one of the first chiplet and the second chiplet comprises a common logic circuitry, coupled to one or more NoC logic circuitry, to perform training, testing, and/or debug across one or more links of the interconnect.

12. The apparatus of claim 1, wherein the first chiplet and the second chiplet have a bump pitch between approximately 25 microns and 1 micron.

13. The apparatus of claim 1, wherein an electrostatic discharge (ESD) circuit is to be omitted for a chiplet of the semiconductor package with bump pitches at or below approximately three microns.

14. The apparatus of claim 1, wherein the interconnect supports a bit error rate (BER) between approximately 10⁻²⁷ and approximately 10⁻³⁰.

15. A System-on-Chip (SoC) comprising:
a processor coupled to a die-to-die interconnect;
the die-to-die interconnect to facilitate communication between a plurality of chiplets;
a first Network-on-chip Controller (NoC) logic circuitry to interface with the die-to-die interconnect and to control a first physical layer module; and
a second NoC logic circuitry to interface with the die-to-die interconnect and to control a second physical layer module,
wherein at least one of the first physical layer module and the second physical layer module is hardened Intellectual Property (IP) module.

16. The SoC of claim 15, wherein at least one of the first NoC logic circuitry and the second NoC logic circuitry is perform one or more lane repairs for the interconnect as a cluster-wide repair.

17. The SoC of claim 15, wherein the physical layer modules on the first chiplet and the second chiplet are to be arranged with dedicated sub-clusters for transmission of data and non-data signals.

18. One or more non-transitory computer-readable media comprising one or more instructions that when executed on a processor configure the processor to perform one or more operations to:
communicate with a first physical layer module of a first chiplet and a second physical layer module of a second chiplet via a chiplet interconnect;
wherein a first Network-on-chip Controller (NoC) logic circuitry is to interface with the chiplet interconnect to control the first physical layer module and wherein a second NoC logic circuitry is to interface with the chiplet interconnect to control the second physical layer module.

19. The one or more non-transitory computer-readable media of claim 18, further comprising one or more instructions that when executed on the processor configure the processor to perform one or more operations to cause at least one of the first NoC logic circuitry and the second NoC logic circuitry to perform one or more lane repair operations for the chiplet interconnect.

20. The one or more non-transitory computer-readable media of claim 18, further comprising one or more instructions that when executed on the processor configure the processor to perform one or more operations to cause at least one of the first NoC logic circuitry and the second NoC logic circuitry to address a communication defect in a link of the interconnect by one of: reducing a width of the link or routing communication around the failed link.
